(19) United States
(12) Patent Application Publication
(10) Pub. No.: US 2024/0371616 A1
(43) Pub. Date: Nov. 7, 2024

(54) PLASMA POWER SUPPLY SYSTEM AND METHOD

(71) Applicant: TRUMPF Huettinger GmbH + Co. KG, Freiburg (DE)

(72) Inventors: Wojciech Gajewski, Warsaw (PL); Moritz Heintze, Freiburg (DE); Jakub Swiatnicki, Warsaw (PL); Mateusz Wiosna, Blonie (PL); Mateusz Baran, Wladyslawow (PL); Grzegorz Toczylowski, Zabki (PL); Bartosz Oliwiak, Warsaw (PL)

(21) Appl. No.: 18/765,382

(22) Filed: Jul. 8, 2024

Related U.S. Application Data
(63) Continuation of application No. PCT/EP2023/050337, filed on Jan. 9, 2023.

(30) Foreign Application Priority Data
Jan. 9, 2022 (DE) 10 2022 100 326.4

(51) Int. Cl. H01J 37/32; C23C 14/34; C23C 14/52; C23C 14/54

(52) U.S. Cl. CPC H01J 37/32935; C23C 14/3485; C23C 14/52; C23C 14/54; H01J 37/32899; H01J 2237/327; H01J 2237/332

(57) ABSTRACT

A plasma power supply system for a plasma processing system is provided. The plasma processing system includes a first plasma source and a second plasma source in adjacent sections of a plasma chamber. The plasma processing system is configured in such a way that in different sections different materials are deposited. A substrate is processed by a plasma in the plasma chamber. The power supply system includes a first power supply configured to supply a first AC power to the first plasma source, a second power supply configured to supply a second AC power to the second plasma source, a first sensor for monitoring a plasma process parameter of the first plasma source, a control unit configured to determine a first operating data related to the plasma process parameter, and control the second power supply based on the first operating data in order to decrease crazing on the substrate.

### CROSS REFERENCE TO RELATED APPLICATIONS

This application is a continuation of International Application No. PCT/EP2023/050337 (WO 2023/131710 A1), filed on Jan. 9, 2023, and claims benefit to German Patent Application No. DE 10 2022 100 326.4, filed on Jan. 9, 2022. The aforementioned applications are hereby incorporated by reference herein.

### FIELD

Embodiments of the present invention relate to a plasma power supply system for a plasma processing system, in particular an in-line plasma coating system, with multiple plasma sources, in particular magnetron plasma sources, in adjacent sections of one plasma chamber where a substrate is placed in several sections at a time or moved from one section to the next section while the sputtering sources are working. Embodiments of the present invention also relate to a plasma processing system and a method of controlling such a plasma processing system.

When coating substrates in a plasma processing system, in particular in an in-line plasma coating system, often different materials are deposited, in sequentially in sections of the plasma chamber. These materials from a magnetron sputter source are applied to the substrate. This process is often called sputtering.

Such plasma processing systems often suffer from so called crazing on the deposited substrates. This undesirable effect has been known for a long time but could so far not fully resolved. There are different approaches discussed and different attempts was made to understand the cause of this crazing as well as to reduce or eliminate it. Some of them are disclosed in the following documents.

### BACKGROUND

In US 2018/0040461 A1 systems, methods, and apparatus are disclosed for reducing crazing in thin film stacks deposited on large area substrates such as glass, for instance architectural glass. It is discussed that crazing can occur once a conductor-insulator-conductor series of films have been deposited, thereby effectively forming a capacitor, and where the substrate spans multiple deposition chambers such the coupling between chambers can cause the effective capacitor voltage to breakdown the insulator layer between the two conductor layers. Here the solution proposed was the grounding of outputs of an AC power supply that assists in deposition of one of the conductor layers. The grounding is via rectified channels, such as diodes, or series of diodes such that the outputs of the AC power supply are precluded from falling below ground potential.

In WO 2019/217155 A1 two other solutions are disclosed: In one example, the system includes a pair of low impedance shunt paths to ground for parasitic AC currents generated from the plasma in the chamber. The low impedance shunts may be provided through a balanced triaxial connection between a power supply of each chamber and the magnetrons of each chamber. In the second example, potential differences between adjacent isolated plasma chambers are minimized through synchronized power supply signals between these chambers.

In WO 2021/058566 A1 the effect of crazing is discussed in detail and a sophisticated power adjustment for each power supply is proposed to reduce this unwanted damage on the substrate. Although this method and system works quite well in most plasma processing systems, in some systems this crazing remains, and further measures are necessary to further reduce this effect.

### SUMMARY

Embodiments of the present invention provide a plasma power supply system for a plasma processing system. The plasma processing system includes a first plasma source and a second plasma source in adjacent sections of a plasma chamber. The plasma processing system is configured in such a way that in different sections different materials are deposited while the first plasma source and the second plasma source are working. A substrate is processed by a plasma in the plasma chamber. The power supply system includes a first power supply configured to supply a first AC power to the first plasma source, a second power supply configured to supply a second AC power to the second plasma source, a first sensor for monitoring a plasma process parameter of the first plasma source, a control unit configured to determine a first operating data related to the plasma process parameter of the first plasma source, and control the second power supply based on the first operating data in order to decrease crazing on the substrate.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 illustrates a plasma processing unit with a plasma power supply system and a diagram of corresponding voltages in such a plasma power supply system, according to some embodiments;

FIG. 2a and FIG. 2b show two alternative schematic views to the plasma processing unit as shown in FIG. 1 according to some embodiments;

FIG. 3a and FIG. 3b illustrate examples of voltage waveforms at the output of a bipolar plasma and power supply, according to some embodiments;

FIG. 4 illustrates another plasma processing unit with a plasma power supply system and a diagram of corresponding voltages in such a plasma power supply system, according to some embodiments;

FIG. 5 shows a chart to illustrate the method steps according to some embodiments;

FIG. 6 shows a typical crazing defect on a substrate; and

FIG. 7 illustrates a schematic representation of a control system according to some embodiments.

### DETAILED DESCRIPTION

Embodiments of the present invention provide a system and/or a method to reduce the grazing effect in a plasma processing system.

In one aspect of the invention the plasma power supply system is configured for a plasma processing system, in particular plasma coating system with multiple plasma sources, in particular magnetron plasma sources, in adjacent sections of one plasma chamber, in particular an in-line plasma processing system, where a substrate is placed in several sections at a time or moved from one section to the next section, and where the plasma processing system is configured in such a way that in different sections different materials are deposited while the sputtering sources are working, and the power supply system may comprise:
a. several power supplies each configured to supply AC power to a corresponding plasma source in a corresponding section,
b. a sensor for monitoring at least one plasma process parameter,
c. a control unit configured to determine an operating data related to the plasma process
parameter and to control at least two of the power supplies in voltage, current, power, and/or phase between adjacent power supplies related to the operating data, in particular to decrease crazing on the substrate.

In a further aspect the plasma power supply system is configured for a plasma processing system with a first plasma source and a second plasma source, both in adjacent sections of one plasma chamber, where the plasma processing system is configured in such a way that in different sections different materials are deposited while the sputtering sources are working, and where a substrate may be processed by the plasma in the plasma chamber, and the power supply system may comprise:
a. a first power supply configured to supply AC power to the first plasma source,
b. a second power supply configured to supply AC power to the second plasma source,
c. a first sensor for monitoring a plasma process parameter of the first plasma source,
d. a control unit configured
   i. to determine a first operating data related to the plasma process parameter of the first plasma source, and
   ii. to control the second power supply related to this operating data, in particular in order to decrease crazing on the substrate.

In a further aspect the output signals of the power supplies are synchronized. Synchronized signals should be signals which are coordinated in time, so for example phase controlled. This further reduces the crazing.

In a further aspect the plasma power supply system is configured for a plasma processing system which may be processed by the plasma in several sections at a time or moved from one section to the next section while the plasma sources are working. This further reduces the crazing.

In a further aspect the control unit is configured to control the second power supply in voltage, current, power, and/or phase of a signal related to the corresponding signal of the first power supply. This further reduces the crazing.

In a further aspect the plasma power supply system further comprises a second sensor for monitoring one plasma process parameter of the second plasma source. This further reduces the crazing.

In a further aspect the control unit is configured
i. to determine a second operating data related to the plasma process parameter of the second plasma source, and
ii. to control the second power supply related to the second operating data in relation to the first operating data. This further reduces the crazing.

In a further aspect the control unit is configured to control the output of one or more of the power supplies in one of the following modes:
a. voltage control,
b. current control,
c. power control.

This further reduces the crazing.

In a further aspect the control unit is part of a power supply. This may further reduce the crazing.

In a further aspect the control unit is divided into several control parts, in particular one control part for each power supply, these control parts comprising a communication interface between each other, so that at least two power supplies are controllable by the control unit (5). This further reduces the crazing.

In a further aspect the sensor for monitoring at least one plasma process parameter is one ore more or a combination of the following:
a. voltage sensor,
b. current sensor,
c. power sensor,
d. phase detector, in particular to detect the phase of voltage and/or current between adjacent power supplies,
e. light absorbing sensor for measuring light in the plasma chamber, in particular in predetermined locations,
f. electrical field strength sensor for measuring electrical fields in the plasma chamber, in particular in predetermined locations,
g. temperature sensor.

This may further reduce the crazing.

In a further aspect the determination of operating data implies determination of operating data which are connected to the effect of crazing. This further reduces the crazing.

In a further aspect a plasma processing unit comprises a plasma power supply system as described above and a plasma processing system with multiple plasma sources in adjacent sections of one plasma chamber where a substrate is placed in several sections at a time or moved from one section to the next section while the sputtering sources are working.

In a further aspect the plasma chamber is partitioned in several sections, in particular by a wall, the wall separating the plasma sources, thereby allowing gas and/or plasma and/or electrical charge carrier to interchange between the sections, in particular by openings in the wall, in particular at the end of the wall. This further reduces the crazing.

In a further aspect the substrate is transported from one section to the adjacent section. This further reduces the crazing.

In a further aspect a method of controlling a plasma power supply system, which supplies power to a plasma processing system with multiple plasma sources in adjacent sections of one plasma chamber, where a substrate is placed in several sections at a time or moved from one section to the next section, and where the plasma processing system is configured in such a way that in different sections different materials are deposited while the sputtering sources are working, comprises the following method steps:
a. several power supplies are supplying AC power to a corresponding plasma source in a corresponding section,
b. monitoring a plasma process parameter of one power supply,
c. determining an operating data related to the plasma process parameter, and
d. controlling the other power supply related to the operating data, in order to decrease crazing on the substrate.

This further reduces the crazing.

It could be found that it is not always the best way just to minimize the voltage between adjacent electrodes of adjacent power supplies. Often this leads not to the needed effect. It was found that with the possibility of the control, in particular a continuous control while the process is running, of the behavior of voltage, current, power and/or phase between adjacent power supplies is possible to reduce a crosstalk, and a stable overall coating process may be achieved.

Monitoring and measuring should be understood as synonyms.

The monitoring of parameters could be execute as described in WO 2021/058566 A1, e.g.

WO 2021/058566 A1 and the corresponding EP 3 796 362 A1 are hereby incorporated by reference in its entirety.

All the method, system, and apparatus aspects of WO 2021/058566 A1 could have an enhanced effect by considering not only measured parameters of the power supply, which is to be controlled, but also will be done related to the operating data which are related to the plasma process parameter of the adjacent plasma source.

So, in a further aspect the control unit may be configured to control the second power supply in a way as disclosed in one or more aspects of WO 2021/058566 A1. For example, the control unit may be configured to determine a feature related to the at least one monitored parameter of the first power supply and to adjust the second power supply signal during the plasma processing to modify, in particular to reduce, the feature. Further aspects are disclosed in WO 2021/058566 A1 and could also be aspects of the invention disclosed in this document.

One or more of the power supplies may be designed to deliver AC power with more than 500 W, in particular more than 5 kW and typically more than 50 kW.

One or more of the power supplies may be designed to deliver AC power in a frequency range between 1 kHz and 200 kHz, in particular between 5 kHz and 100 kHz.

The output power of one or more of the power supplies may be connected with two targets in the plasma chamber, respectively. So, both targets may be driven as cathodes and anodes alternately, respectively.

One or more of the power supply signals that are adjusted may be a current-, a voltage-, or a power-controlled signal. Advantageously it is a current-controlled signal.

The monitored plasma process parameter can be for example voltage, current, power, reflected waves (at a basic frequency or other frequency) and/or a combination of the aforementioned as, for example, the impedance of the plasma process.

The monitored plasma process parameter may be different from the power supply signal that is adjusted. For example: If the power supply signal is a current-controlled signal, the monitored parameter may be a voltage. Or, if the power supply signal is a voltage- or power-controlled signal, the monitored parameter may be a current.

The monitored plasma process parameter can be the voltage of one of the targets against the potential of the plasma chamber, which may be ground or earth.

The monitored plasma process parameter can additionally be the voltage of the other target against the potential of the plasma chamber, which may be ground or earth.

The monitored plasma process parameter can be in particular the voltage between the two targets in the plasma chamber.

The monitored plasma process parameter may also be a parameter measured in the plasma chamber or aside the plasma chamber, for example through a window. The monitored or measured parameter may be light, pressure, discharge, electrical or magnetic field strength or another signal in the plasma chamber.

The monitored plasma process parameter can be measured with a sampling rate which is higher than the frequency of the AC power supply, in particular more than ten times higher than the frequency of the AC power supply.

The monitored plasma process parameter may be a derivate of a measured value.

Then also the velocity or rate of change in a measured value may be the source for the determination of the feature.

The monitored plasma process parameter may be a filtered value. Then also a part of the frequency spectrum in a measured value may be the source for the determination of the feature.

The monitored plasma process parameter may be a time framed value. That should mean that a predefined time frame is laid over the measured value, and only a time interval of the measured value will be the source for the determination of the feature.

The monitored plasma process parameter may be, but should not be limited to, an electric potential between:
a. the electrodes arranged within the plasma chamber, or
b. one of the electrodes arranged within the plasma chamber and a reference electrode, or
c. both electrodes arranged within the plasma chamber and a reference electrode, where the reference electrode may be grounded or floating.

If the second power supply is controlled e.g., in voltage, current, power, and/or phase of a signal related to the corresponding signal of the first power supply, then at least one parameter is changed. If one of the parameters is changed, one or more of the other parameters may have to be changed as well in order to keep the power constant. For example, if the duty cycle is changed, i.e., the waveform of the power supply signal component is changed, the amplitude of the power supply signal component may have to be changed as well. The amplitude, waveform and frequency of a power supply signal component may be the parameter set or part of the parameter set applied for producing the power supply signal.

At least some of the method steps may be performed in response to a user demand. For example, in the case of an older power supply, where monitoring and/or detecting can only be done using external equipment to determine the feature, the method can be triggered by a user.

Alternatively, at least some of the method steps may be performed in response to detecting that at least one monitored parameter exceeds a threshold border. Hence the improvement of the plasma process can be initiated if a monitored parameter exceeds a threshold border. The threshold border can be given, or user defined or determined by algorithm, such as a machine learning algorithm and/or artificial intelligence algorithms.

For the method and system with machine learning algorithm and/or artificial intelligence algorithms the event of crazing in the substrate should additionally be monitored. With that monitoring and analysis, a set of training- and test-data may be recorded. In such a way the method and the system may be trained and, in particular, checked and, in particular, continuously improved.

Alternatively, at least some of the method steps may be performed in response to statistical data obtained from a range of power supplies supplying power to a plasma process. In particular, the inventive method can be activated as a background application and use statistical data from a range of power supplies available in a central processing system, in particular a cloud computing system, to perform sophisticated improvement and return settings to the power supply to regulate the operating parameters, such as voltage and/or current waveform, amplitude and frequency. Statistical data may be obtained from different power supplies, in particular data collected in the cloud from power supplies from different places and different plasma processes. A neural network may be used to decide which parameters and/or features may be better qualified than other ones and the ones which are better qualified may get a higher relevance in the respective method steps.

One or more of the power supplies may be an MF power supply. An MF power supply may be designed to deliver an output power where the output voltage and/or output current are formed sinusoidal.

One or more of the power supplies may be a bipolar supply. A bipolar power supply maybe designed to deliver an output power where the output voltage and/or output current are formed rectangular or stepwise rectangular or in a predefined way as described in DE 10 2009 002 684 A1 or DE 10 2014 220 094 A1 which are hereby incorporated by reference. A bipolar supply has the advantage that the duty cycle, voltage, and frequency can be adjusted without changing the power. In particular, the power can be kept constant. Thus, the power delivered to the plasma process can be kept constant, but the parameters for creating the power can be adjusted. This can lead to the prevention of crazing.

In bipolar plasma processes current controlled power supplies may be used. That should mean that the adjustable power supply signal follows a set value of predefined current. The resulting voltage then depends on the impedance of the plasma, which may be very fast changing. So, the voltage very often does not directly follow the current waveform. It has been found, that not every unproportionality between current and voltage is reason to crazing. But it has also be found that there are typical peculiarities that may lead to crazing.

One or more of the power supplies may be designed to balance the power between both outputs as described for example in EP 1 593 143 B1 which is hereby incorporated by reference.

Furthermore, a bipolar power supply may be configured to supply power to two targets simultaneously. In particular, the bipolar power supply may be configured to supply a dual magnetron sputtering arrangement with power.

The control unit may be integrated in the power supply, or the control unit may be external to the power supply. If the control unit is external to the power supply, it can be used for several power supplies.

The sensor may be positioned at the power supply output or in the vicinity of the electrode, in particular in the vicinity of the target. The monitored parameter can be measured directly at the power supply output and/or on the target. In particular, the measurement can be taken at the closest point accessible for such measurements, for example at the cable connection to the target end-blocks.

Compared to previous solutions, the control unit according to embodiments of the invention, which is configured to perform the inventive method, can actively minimize the root cause of crazing by minimizing the feature, in particular by minimizing the target-to-target potential and/or the target-to-ground potential. The inventive method can be used as continuously adapting method. The control unit can thus continuously react to condition changes in the system, for example, due to progressive growth of a parasitic coating on system elements or cyclic modification of the working conditions of the power supply itself.

The control unit may comprise a user interface for triggering an adjustment of the power supply signal. In particular, a user can trigger the inventive method by using the user interface.

The plasma processing system may comprise several power supplies that exchange data with a cloud computing system. Hence, suitable parameters obtained for one power supply can be used for other power supplies, supplying power to similar plasma processes.

Further features and advantages of the embodiments of the invention are presented in the following detailed description, with reference to the figures of the drawing. The features shown there are not necessarily to be understood in terms of scale and are shown in such a way that the features according to embodiments of the invention can be made clearly visible. The various features can each be implemented individually or collectively in any combination in the case of variants of the invention.

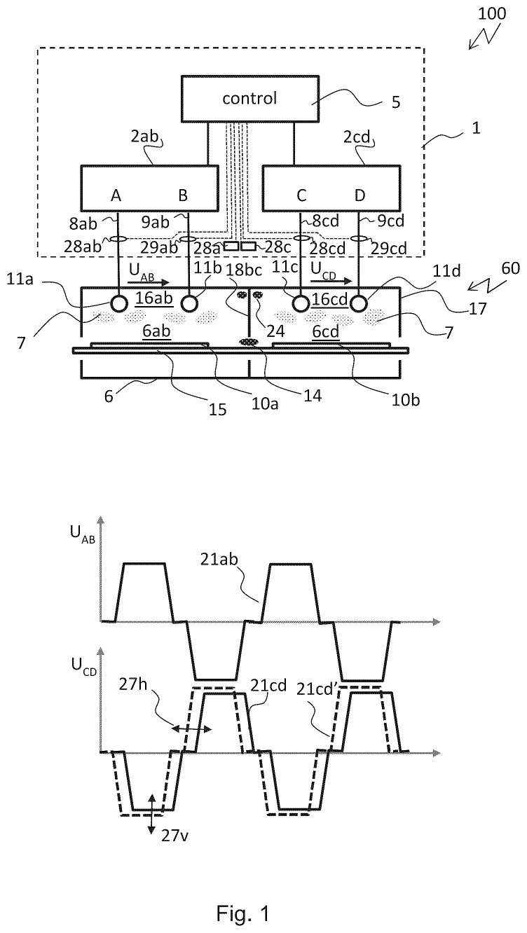

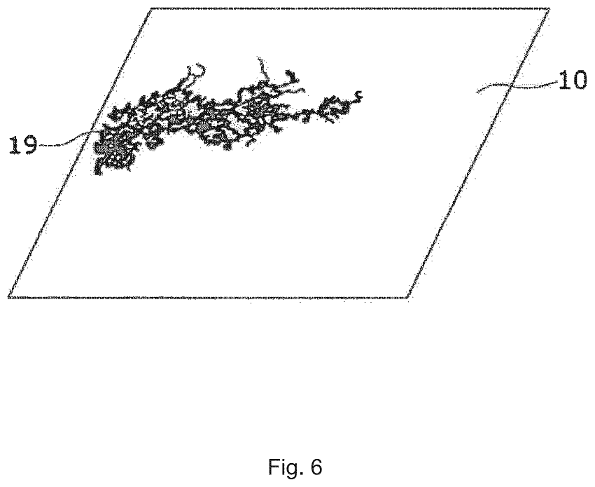

FIG. 1 shows a plasma processing unit 100. This may be an in-line coater. The plasma processing unit 100 comprises a plasma power supply system 1 and a plasma processing system 60. The plasma processing system 60 comprises a plasma chamber 6 for processing substrates 10a, 10b. One example of such a substrate could be the substrate 10 of FIG. 6, where an unwanted crazing 19 had occurred. Embodiments of the present invention can reduce such crazing effects on the substrate. In FIG. 1 the substrates 10a, 10b are disposed on a substrate carrier 15. This could be rollers as discussed in WO 2021/058566 A1, e.g. The plasma power supply system 1 comprises a first power supply 2ab with outputs A and B connected to electrodes 11a, 11b via power lines 8ab, 9ab. The electrodes 11a, 11b are arranged within the plasma chamber 6, more precise in the first section 6ab of the plasma chamber 6. By supplying power to the electrodes 11a, 11b a plasma 7 may be formed and maintained in the first section 6ab of the plasma chamber 6. This is called the first plasma source 16ab. The plasma power supply system 1 comprises further a second power supply 2cd with outputs C and D connected to electrodes 11c, 11d via power lines 8cd, 9cd. The electrodes 11c, 11d are arranged within the plasma chamber 6, more precise in the second section 6cd of the plasma chamber 6. By supplying power to the electrodes 11a, 11b a plasma 7 may be formed and maintained in the second section 6cd of the plasma chamber 6. This is called the plasma source 16cd. The electrodes 11a-11d may be rotating electrodes. The plasma may be enhanced by magnets; so that the plasma process may be a magnetron plasma process. The plasma process may be for sputtering material from electrodes 11a-11d. Such electrodes 11a-11d in a plasma processing system 60 are also called target. The plasma processing system 60 may be designed for deposition of material on the substrate 10a, 10b, 10. It may be a PVD, CVD reactive plasma process or the like. The power supplies 2ab, 2cd may be an AC power supply, delivering an AC Signal to the electrodes 11a-11d. Then each pair of electrodes 11a, 11b, and 11c, 11d may work as cathodes and anodes alternatively. With an in-line coater an in-line plasma processing system is meant, where a substrate 10, 10a, 10b is placed in several sections 6ab, 6cd at a time or moved from one section 6ab to the next section 6cd. The plasma processing system 60 may be configured in such a way that in different sections 6ab, 6cd different materials are deposited or coated while the sputtering sources 16ab, 16cd are working.

The plasma power supply system 1 comprises further one or several sensors 28a, 28c, 28ab, 29ab, 28cd, 29cd for monitoring at least one plasma process parameter. This could be one or more or a combination of the following:
a. Voltage sensor,
b. Current sensor,
c. Power sensor,
d. Phase detector, in particular to detect the phase of voltage and/or current between adjacent power supplies,
e. Light absorbing sensor 28a, 28c for measuring light in the plasma chamber, in particular in predetermined locations,
f. Electrical field strength sensor 28a, 28c for measuring electrical fields in the plasma chamber, in particular in predetermined locations,
g. temperature sensor 28a, 28c, or similar sensors to monitoring at least one plasma process parameter.

In particular the sensors could be voltage sensors configured to measure the voltage between the power lines 8ab, 8cd, 9ab, 9cd and the grounding 17 of the plasma chamber 6. With such a measurement it is possible do determine the voltages U_{AB} between the power lines 8ab, 9ab and U_{CD} between the power lines 8ab, 8cd. It is also possible to determine the voltage between the adjacent power lines 9ab and 8cd. With such a measurement it is also possible to determine a phase between adjacent power supplies.

Such sensors could be placed inside or outside of the power supplies 2ab, 2cd. It may be advantageous to place them outside of the plasma chamber 6 but as close as possible to the electrodes 11a-11d. Special measurement equipment to be placed here could be used, so called electrode-measurement-box, anode-voltage-box, cathode-voltage-box, anode-current-box, etc.

These sensors deliver the monitored data to the control unit 5. The control unit 5 is configured to determine an operating data related to the plasma process parameter. It is further configured to control at least the two power supplies 2ab, 2cd in voltage, current, power, and/or phase between adjacent power supplies related to the operating data, in particular to decrease crazing on the substrate 10, 10a, 10b. The control unit 5 may be configured to control the output of one or more of the power supplies in one of the following modes:
a. voltage control,
b. current control,
c. power control.

In this way it may be possible to control the power supplies in different ways. Firstly, in a current control mode, voltage control mode, or power control mode and secondly, in a superimposed control mode to reduce crazing related to determined data from the other power supply.

The plasma chamber 6 is partitioned in several sections 6ab, 6cd. This may be done by a wall 18bc. The wall 18bc separating the plasma sources 16ab, 16cd, allows the interchange of gas and/or plasma and/or electrical charge carrier between the sections 6ab, 6cd, in particular by openings in the wall 18bc, in particular at the end of the wall 18bc. The end of the wall 18bc may be located where the wall 18bc comes next to the substrates 10, 10a, 10b.

Such a wall 18bc may have several effects, some of them wanted, some of them not wanted.

A typical wanted effect is the separation of the sections 6ab, 6cd from each other, so that different deposition sections with different deposition material and processes are possible as well as intermediate cleaning sections may interfere as less as possible with each other.

A typical unwanted effect are plasma clouds 24 building up in the corners of the sections. These plasma clouds 24 could be a cause for crazing. So, these clouds 24 may be monitored by a by a sensor 28a, 28b, such as a light absorbing sensor, or electrical field strength sensor, e.g. These clouds 24 may be controlled by the control unit 5, 5ab, 5cd in order to decrease crazing on the substrate 10a, 10b. These clouds 24 may be controlled in particular by synchronizing the power supplies 2ab, 2cd in phase. Thereby it is no absolute necessity to synchronize the power supplies 2ab, 2cd in a way that the voltage between the adjacent electrodes 11b, 11c of two different adjacent plasma sources 16ab, 16cd is as low as possible. It could be a better solution to allow a wanted phase delay between both adjacent electrodes 11b, 11c of two different adjacent plasma sources 16ab, 16cd to control the clouds 24 and thereby decrease, in particular minimize, crazing.

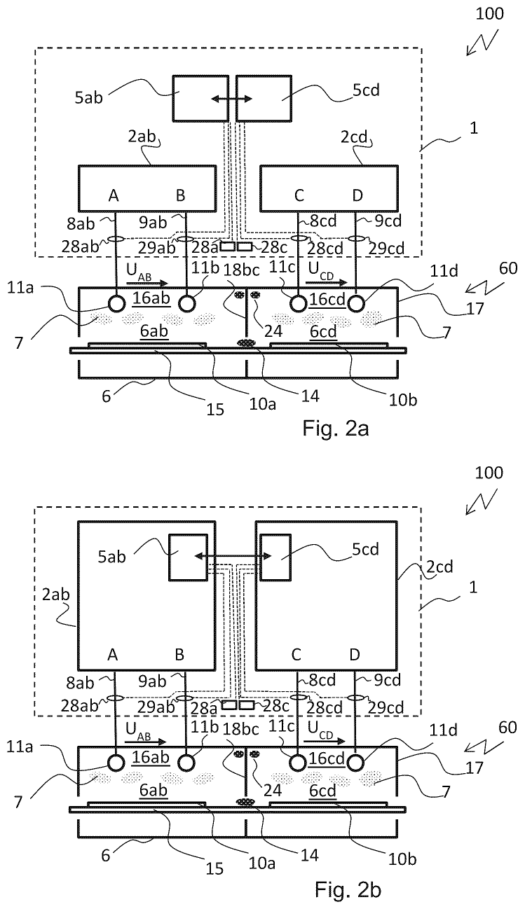

Another typical unwanted effect is the carrier exchange in the gap between the wall 18bc and the substrate 10a, 10b which is shown in FIG. 1, FIG. 2a and FIG. 2b as a carrier region 14. This carrier region 14 could also be a cause for crazing. So, this carrier region 14 may be monitored by a sensor 28a, 28b, such as a light absorbing sensor, or electrical field strength sensor, e.g. This carrier region 14 may be controlled by the control unit 5, 5ab, 5cd in order to decrease crazing on the substrate 10a, 10b. In particular by synchronizing the power supplies 2ab, 2cd in phase. Thereby is no absolute necessity to synchronize the power supplies 2ab, 2cd in a way that the voltage between the adjacent electrodes 11b, 11c of two different adjacent plasma sources 16ab, 16cd is as low as possible. It could be a better solution to allow a wanted phase delay between both adjacent electrodes 11b, 11c of two different adjacent plasma sources 16ab, 16cd to control the carrier region 14 and thereby decrease, in particular minimize, crazing.

In the diagram of FIG. 1 a typical voltage U_{AB} of the first power supply 2ab is shown as a signal 21ab.

In the second diagram a typical voltage U_{CD} of the second power supply 2cd is shown as a signal 21cd. This voltage may be changes in phase 27h as a signal 21cd′.

In another aspect, this voltage may be changed in amplitude 27v.

Crazing defects on the substrate may occur in particular on the surface of insulating materials during sputtering deposition and may damage the product, generating significant waste and financial losses in production. Especially in the case of Large Area Coating (LAC) for architectural glass manufacturing each occurrence of crazing hinders continuity of production, and in extreme cases forces the production cycle to stop before scheduled system maintenance.

In the case of sputtering deposition of functional coatings on glass, crazing has been reported to occur at different stages of the multilayer structure deposition. As more and more glass coaters shift from an MF-driven dual magnetron sputtering to bipolar power supplies the versatility of frequency and current/voltage output waveform modifications available in bipolar power supplies unintentionally led to increased probability of crazing occurrence for some parameters combinations. In the event of excessive crazing typically a thorough mechanical cleaning of vacuum chamber components is undertaken to eliminate the loss of glass product.

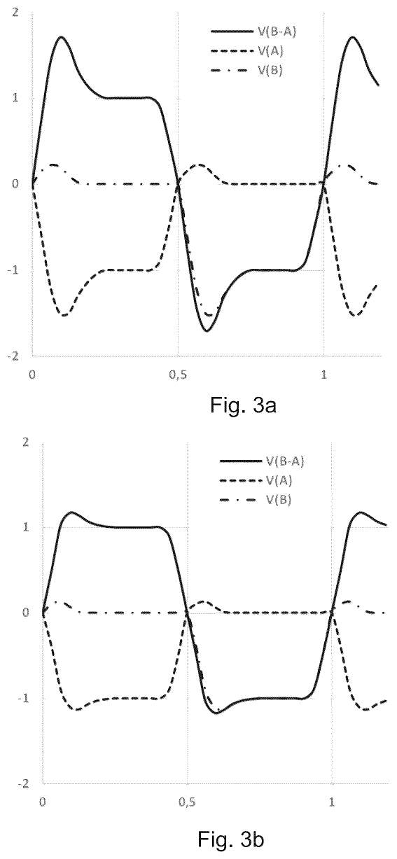

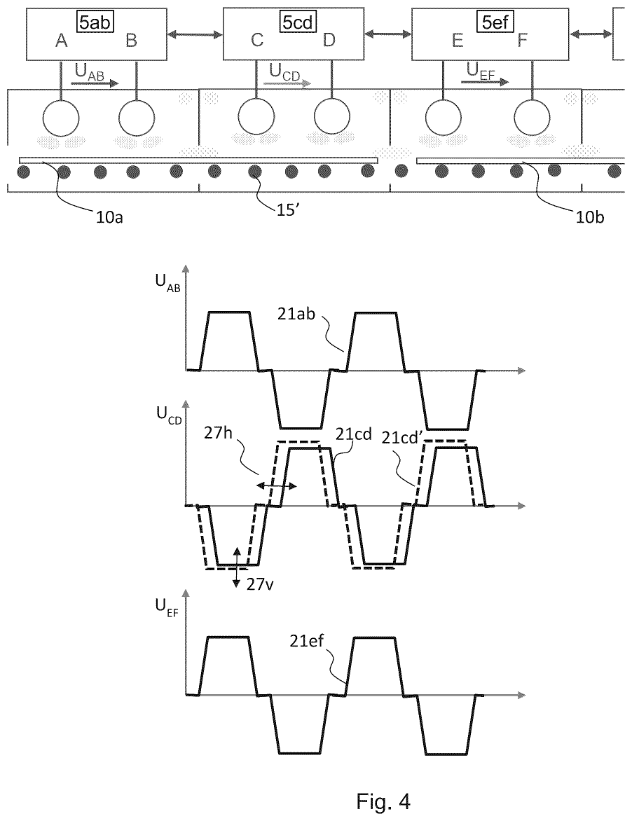

It has been found that the occurrence of crazing may be attributable to accumulation of charge on the surface of coated glass. The glass which undergoes the deposition is moved under the plurality of magnetron arrangements (typically dual target magnetrons) by rollers, shown as an example in FIG. 4, reference number 15′, made of insulation material. Glass itself is also a dielectric material very often even with the deposited coatings and since it has no electrical contact with the chamber walls, one may assume it is on a floating potential. An in-depth analysis of collected data allowed to identify a relationship between the occurrence of crazing and the electrical potential of an anode. Since the dynamics of plasma species depend on the driving force for the plasma discharge generation (the voltage and current waveform), a series of measurements of the anode voltage as a function of the bipolar power supply setting configuration such as current waveform have been performed. It could be found that in changing the waveform of current, voltage and/or power the crazing effect could be influenced in a positive way. One very successful parameter setting for systems under investigation are presented schematically in FIGS. 3a and b as it will be explained in more detail later.

The voltage applied at the output of the power supplies 2ab, 2cd or close to the electrodes 11a-11d is—when a bipolar power supply is used, as explained in WO 2021/058566 A1, e.g.,—typically of a square wave shape. In a practical system, the square wave shows a voltage overshoot at the beginning of each pulse. A typical example is shown in FIG. 3a by V(B-A). When the voltages of each magnetron are measured to ground 17, it is seen that the voltage overshoot is present on both the negative pulse and the positive pulse, shown as V(A) and V(B). As long as adjacent power supplies are operated with a random phase relation of the waveforms, these voltage overshoots can be a significant portion of the applied pulse voltage, varying as the phase between the adjacent power supplies varies.

When the output pulses power supplies are synchronized, the height of the signal overshoot can be controlled, an exampled of improved output signals is shown in FIG. 3b. This effect may be further improved, when the synchronization and/or control of the output of one power supply will be done related to the operating data which are related to the plasma process parameter of the adjacent plasma source. When the whole control method and system aspects described in WO 2021/058566 A1 further consider not only measured parameters of the power supply which is to be controlled, but also will be done related to the operating data which are related to the plasma process parameter of the adjacent plasma source, this effect could be further improved.

Synchronizing multiple plasma power supplies in a plasma process was proposed in “www.advancedenergy.com/globalassets/resources-root/data-sheets/ascent_dms_data-sheet.pdf” (Advanced Energy Ascent DMS data Sheet) to enhance the lateral uniformity, in a system where the substrates are coated under stationary conditions.

In a normal production cycle of coated glass, the crazing effect is not the only parameter influencing the quality of the product and the efficiency of the production process. If the coating layer stack configuration includes sputtering from heavily arcing targets in reactive atmosphere indicators such as arc suppression efficiency or target condition need to be taken into account. For these reasons, the improvement of the bipolar power supply settings for anode voltage minimization could include keeping the operation within the recommended parameter range. For example, if silicon targets are used for reactive sputtering of a SiO₂ layer the frequency can be varied in a range allowing operation without a risk of nodules formation. Nodules, an arc-related local damage, of target surface, may arise if arc suppression mechanisms are misused or the operation frequency is lower than a critical value.

FIG. 4 shows another plasma processing unit with a plasma power supply system and a diagram of corresponding voltages in such a plasma power supply system.

Most of the parts shown here are similar to those of FIG. 1. A third plasma power supply with outputs E and F and a Voltage U_{EF} between these outputs is shown here. This FIG. 4 should just show that embodiments of the invention are not limited to two power supplies and two plasma sections as shown in FIG. 2. Several power supplies with corresponding plasma sources and control part (5ap, 5cd, 5ef) could work alike.

The diagrams of FIG. 4 show a further voltage U_{EF} as a signal 21ef.

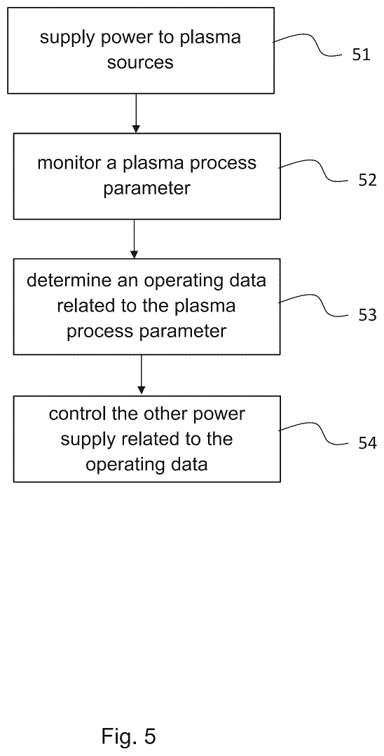

FIG. 5 shows a chart of the method steps of the method of controlling a plasma power supply system 1, which supplies power to a plasma processing system 60 with multiple plasma sources 16ab, 16cd in adjacent sections 6ab, 6cd of one plasma chamber 6 where a substrate 10, 10a, 10b is placed in several sections 6ab, 6cd at a time or moved from one section 6ab to the next section 6cd while the sputtering sources 16ab, 16cd are working.

In a first method step 51 several power supplies are supplying AC power to a corresponding plasma source 16ab, 16cd in a corresponding section 6ab, 6cd.

In a second method step 52 a plasma process parameter of one power supply 2ab is monitored.

In a third method step 53 an operating data related to the plasma process parameter is determined.

In a fourth method step 54 the other power supply 2cd is controlled related to the operating data, in particular to decrease crazing on the substrate 10, 10a, 10b.

FIG. 6 shows a typical crazing damage 19 on a glass substrate 10. So, a crazing damage 19 has a typical shape with a branching propagation and is therefore clearly distinguishable from other damages such as spots or periodical change in color or homogeneity of a deposition.

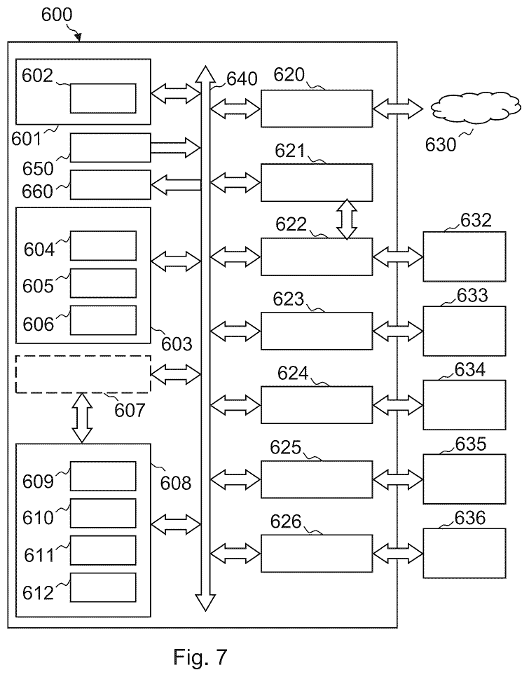

FIG. 7 shows a schematic representation of an embodiment of a control system 600 which is suitable for carrying out instructions for carrying out one or more aspects of the methods in one of the apparatuses of the embodiments of the present invention. For example, the control system 600 can be used to implement the control unit 5, the control unit parts 5ab, 5cd, 5ef or similar of FIGS. 1 to 4. The components in FIG. 7 are to be understood as examples and do not restrict the scope of the use or functionality of hardware, software, firmware, embedded logic components, or a combination of several such components for implementing embodiments of the present invention. Some or all of the illustrated components can be part of the control system 600.

In this embodiment, the control system 600 contains at least one processor 601, such as a central processing unit (CPU, DSP) or a programmable logic module (PLD, FPGA). The control system 600 may also include a main memory 603 and a data memory 608, both of which communicate with one another and with other components via a bus 640. Bus 640 may also include a display 632, one or more input devices 633, one or more output devices 634, one or more storage devices 635, and various storage media 636 with each other and with one or more devices from processor 601, memory 603, and connect to data memory 608. All of these elements can be coupled to bus 640 directly or via one or more interfaces 622, 623, 624, 625, 626 or adapters.

The memory 603 may comprise various components including, but is not limited to, a random-access memory component e.g., RAM 604 in particular a static RAM “SRAM”, a dynamic RAM “DRAM, etc., a read-only component, e.g., ROM 605, and any combination thereof. The ROM 605 can also function to store data and Instructions to communicate unidirectionally to the processor (s) 601, and the RAM 604 can also act to communicate data and instructions bi-directionally to the processor (s) 601.

The read-only memory (ROM) 608 is bidirectionally connected to the processor or processors 601, optionally through a memory control unit 607. The read-only memory 608 offers additional storage capacity. The memory 608 can be used to store the operating system 609, programs 610, data 611, applications 612, application programs, and the like. Often, but not always, storage 608 is a secondary storage medium (such as a hard drive) that is slower than primary storage (e.g., storage 603). For example, memory 608 may also include a magnetic, optical, transistorized, solid-state storage device (e.g., flash-based systems), or a combination of any of the above. The information memory 608 can be integrated into the memory 603 as virtual memory in suitable cases.

The data bus 640 connects a variety of subsystems. Bus 640 can be any of several types of bus structures, e.g., a memory bus, a memory controller, a peripheral bus, a local bus, and any combinations thereof using a variety of bus architectures. Information and data can also be displayed via a display 632. Examples of a display 632 include, but are not limited to, a liquid crystal display (LCD), an organic liquid crystal display (OLED), a cathode ray tube (CRT), a plasma display, and any combination thereof. The display 632 can be connected to processor (s) 601, memories 603, 608, input devices 633, and other components via the bus 640.

The bus 640 can connect all of the aforementioned components with a network interface 620 to an external network 630. This can be e.g. a LAN, WLAN, etc. It can establish a connection to other storage media, servers, printers and display devices. It can have access to telecommunication devices and the Internet. The bus 640 can connect all of the aforementioned components to a graphics controller 621 and a graphics interface 622, which can be connected to at least one input device 633.

The bus 640 can connect all of the aforementioned components to an input interface 623 that can be connected to at least one input device 633.

The bus 640 can connect all of the aforementioned components to an output interface 624, which can be connected to at least one output device 634. An output device 634 may comprise an illuminated display, an LED display, a display, e.g., LCD, OLED, etc., or an interface to such a device.

The bus 640 can connect all of the aforementioned components to a memory access interface 625, which can be connected to at least one memory device 635. The bus 640 can connect all of the aforementioned components to a further memory access interface 626, which can be connected to at least one storage medium 636. A storage device 635 or a storage medium 636 can be, for example, a solid-state memory, a magnetic memory or an optical memory, in particular a non-volatile memory. The storage medium can be separated from the control system during operation of the control system without data being lost.

Display 632, input device 633, output device 634, storage device 635, storage medium 636 can each be arranged outside the control system 600 or integrated into it. They can also be connected to the control system 600 via a connection to the Internet or other network interfaces.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A plasma power supply system for a plasma processing system, the plasma processing system comprising a first plasma source and a second plasma source in adjacent sections of a plasma chamber, wherein the plasma processing system is configured in such a way that in different sections different materials are deposited while the first plasma source and the second plasma source are working, and wherein a substrate is processed by a plasma in the plasma chamber,
the power supply system comprising:
a. a first power supply configured to supply a first AC power to the first plasma source,
b. a second power supply configured to supply a second AC power to the second plasma source,
c. a first sensor for monitoring a plasma process parameter of the first plasma source,
d. a control unit configured to:
i. determine a first operating data related to the plasma process parameter of the first plasma source, and
ii. control the second power supply based on the first operating data, in order to decrease crazing on the substrate.

2. The plasma power supply system according to claim 1, wherein output signals of the first power supply and the second power supply are synchronized.

3. The plasma power supply system according to claim 1, wherein the plasma processing system is configured to process the substrate by the plasma in several sections at a time, or move the substrate from one section to a next section while the first plasma source and the second plasma source are working.

4. The plasma power supply system according to claim 1, wherein the control unit is configured to control the second power supply in voltage, current, power, and/or phase of a signal based on a corresponding signal of the first power supply.

5. The plasma power supply system according to claim 1, further comprising a second sensor for monitoring a plasma process parameter of the second plasma source.

6. The plasma power supply system according to claim 5, wherein the control unit is further configured to:
i. determine a second operating data related to the plasma process parameter of the second plasma source, and
ii. control the second power supply based on the second operating data in relation to the first operating data.

7. The plasma power supply system according to claim 1, wherein the control unit is further configured to control an output of one or more of the first power supply and the second power supply in one of following modes:
a. voltage control,
b. current control, or
c. power control.

8. The plasma power supply system according to claim 1, wherein the control unit is part of the first power supply or the second power supply.

9. The plasma power supply system according to claim 1, wherein the control unit is divided into several control parts, each respective control part for each of the first power supply and the second power supply, each control part comprising a communication interface for communication between each other, so that the first power supply and the second power supply are controllable by the control unit.

10. The plasma power supply system according to claim 1, wherein the first sensor for monitoring the plasma process parameter of the first plasma source comprises one or more of:
a. a voltage sensor,
b. a current sensor,
c. a power sensor,
d. a phase detector to detect a phase of voltage and/or current between the first power supply and the second power supply,
e. a light absorbing sensor for measuring light in the plasma chamber in predetermined locations,
f. an electrical field strength sensor for measuring electrical fields in the plasma chamber in predetermined locations, or
g. a temperature sensor.

11. The plasma power supply system according to claim 1, wherein the determining the first operating data comprises determining operating data related to the crazing.

12. A plasma processing unit comprising a plasma power supply system according to claim 1, and a plasma processing system with multiple plasma sources in multiple sections of a plasma chamber, wherein a substrate is placed in several sections of the multiple sections at a time or moved from one section to a next section, wherein the plasma processing system is configured in such a way that in different sections different materials are deposited while the multiple plasma sources are working.

13. The plasma processing unit according to claim 12, wherein the plasma chamber is partitioned in the multiple sections by a wall, the wall separating the multiple plasma sources, thereby allowing gas and/or plasma and/or electrical charge carrier to interchange between the sections by openings in the wall.

14. The plasma processing unit according to claim 1, wherein the substrate is transported from one section to an adjacent section.

15. A method of controlling a plasma power supply system, which supplies power to a plasma processing system with multiple plasma sources in multiple sections of a plasma chamber, wherein a substrate is placed in several sections of the multiple sections at a time or moved from one section to a next section, and wherein the plasma processing system is configured in such a way that in different sections different materials are deposited while the multiple plasma sources are working,
the method comprising:
a. supplying an AC power by a respective power supply to a corresponding plasma source in a corresponding section,
b. monitoring a plasma process parameter of a first power supply of the multiple power supplies,
c. determining an operating data related to the plasma process parameter, and
d. controlling a second power supply of the multiple power supplies based on the operating data, in order to decrease crazing on the substrate.
